(19) United States
(12) Patent Application Publication
(10) Pub. No.: US 2010/0176495 A1
(43) Pub. Date: Jul. 15, 2010

(54) LOW COST FABRICATION OF DOUBLE BOX BACK GATE SILICON-ON-INSULATOR WAFERS

(75) Inventors: Jack O. Chu, Manhasset Hills, NY (US); Robert H. Dennard, Croton-On-Hudson, NY (US); John A. Ott, Greenwood Lake, NY (US); Devendra K. Sadana, Pleasantville, NY (US); Leathen Shi, Yorktown Heights, NY (US)

Correspondence Address: CANTOR COLBURN LLP-IBM YORKTOWN, 20 Church Street, 22nd Floor, Hartford, CT, 06103, US

(73) Assignee: International Business Machines Corporation, Armonk, NY (US)

(21) Appl. No.: 12/352,052

(22) Filed: Jan. 12, 2009

(51) Int. Cl. H01L 23/58; H01L 21/30

(52) U.S. Cl. 257/635; 438/458; 257/E21.085; 257/E23.008

(57) ABSTRACT

A semiconductor wafer structure for integrated circuit devices includes a bulk substrate; a lower insulating layer formed on the bulk substrate; an electrically conductive layer formed on the lower insulating layer; an upper insulating layer formed on the electrically conductive layer, the upper insulating layer formed from a pair of separate insulation layers having a bonding interface therebetween; and a semiconductor layer formed on the upper insulating layer.

### BACKGROUND

The present invention relates generally to semiconductor device manufacturing techniques and, more particularly, to low cost fabrication of double buried oxide (BOX), back gate (DBBG) silicon-on-insulator (SOI) wafers.

In SOI technology, a thin silicon layer is formed over an insulating layer, such as silicon oxide, which in turn is formed over a bulk substrate. This insulating layer is often referred to as a buried oxide (BOX) layer or simply a BOX. For a single BOX SOI wafer, the thin silicon layer is divided into active regions by shallow trench isolation (STI), which intersects the BOX, providing a total isolation for the active regions. Sources and drains of field effect transistors (FETs) are formed, for example, by ion implantation of N-type and/or P-type dopant material into the thin silicon layer with a channel region between the source and drain using the gate pattern to self-define the channel region. Prior to the formation of sources and drains, gates are formed on top of the channel region, for example, by deposition of a gate dielectric and conductor on the top surface of the thin silicon, followed by photolithographic patterning, and etching. Back gates can also be formed under the active region on a single BOX SOI wafer using the BOX layer as the back-gate dielectric, and can be defined by either P+ or N+ implantation. Transistors with back gates typically use relatively thin silicon and BOX layers to enable fully depleted device operation with a threshold voltage which is responsive to the back gate. Such FETs built in thin SOI technology with back gates have significant advantages such as, for example, reduced short channel effects, less threshold variability due to body doping fluctuations, and ability to use the back gate voltage to adjust the threshold.

In addition to single BOX SOI substrates, double BOX substrates may also be used in forming transistor devices having dual gate electrodes formed both above and below the transistor channel region. The conductive gate material formed below the device channel, also referred to as a back gate, is separated from the SOI active layer by a first BOX, and is separated from the substrate by a second BOX.

Typically, in order to manufacture such a double BOX wafer having an upper BOX and a lower BOX therein, at least one preformed SOI wafer is used as a starting substrate. However, the cost of preformed SOI wafers is usually several times that of device-quality bulk silicon wafers. Thus, purchasing SOI wafers as a starting substrate adds to the cost of forming a double BOX SOI wafer. Accordingly, it would be desirable to be able to fabricate a substrate such as a double BOX back gate (DBBG) SOI wafer at a lower cost with respect to conventional processes.

### SUMMARY

In an exemplary embodiment, a method of forming a semiconductor wafer structure for integrated circuit devices includes forming a first substrate portion having a first bulk substrate, a first insulating layer formed on the first bulk substrate, an electrically conductive layer formed on the first insulating layer, and a second insulating layer formed on the electrically conductive layer; forming a second substrate portion having a second bulk substrate, a sacrificial layer formed on the second bulk substrate, a semiconductor layer formed on the sacrificial layer and a third insulating layer formed on the semiconductor layer; bonding the first substrate portion to the second substrate portion so as to define a bonding interface between the second and third insulating layers; separating the resulting bonded structure at a location within the second bulk substrate or the sacrificial layer and removing the second bulk substrate; and removing any remaining portion of the sacrificial layer so as to define a double buried insulator back gate semiconductor-on-insulator structure, wherein the first insulating layer comprises a lower insulating layer, the bonded second and third insulating layers together comprise an upper insulating layer, the semiconductor layer comprises a semiconductor-on-insulator layer, the electrically conductive layer comprises a back gate layer, and the first bulk substrate comprises a bulk substrate of the double buried insulator back gate semiconductor-on-insulator structure.

In another embodiment, a method of forming a double buried insulator back gate semiconductor-on-insulator wafer structure for integrated circuit devices includes forming a first substrate portion having a first bulk substrate, a first insulating layer formed on the first bulk substrate, an electrically conductive layer formed on the first insulating layer, and a second insulating layer formed on the electrically conductive layer; forming a second substrate portion having a second bulk substrate, a sacrificial layer formed on the second bulk substrate, a semiconductor layer formed on the sacrificial layer and a third insulating layer formed on the semiconductor layer; implanting a hydrogen species through the third insulating layer and the semiconductor layer, stopping within or beyond the sacrificial layer; bonding the first substrate portion to the second substrate portion so as to define a bonding interface between the second and third insulating layers; performing an annealing procedure so as to create a front of connecting voids corresponding to a location of the hydrogen species; separating the bonded structure along the void front; and removing any remaining part of the second bulk substrate and the sacrificial layer on the semiconductor layer so as to define a double buried insulator back gate semiconductor-on-insulator wafer structure, wherein the first insulating layer comprises a lower insulating layer, the bonded second and third insulating layers together comprise an upper insulating layer, the semiconductor layer comprises a semiconductor-on-insulator layer, the electrically conductive layer comprises a back gate layer, and the first bulk substrate comprises a bulk substrate of the double buried insulator back gate semiconductor-on-insulator wafer structure.

In another embodiment, a method of forming a double buried oxide (BOX), back gate (DBBG) silicon-on-insulator (SOI) wafer structure for integrated circuit devices includes forming a first substrate portion having a first bulk silicon substrate, a first oxide layer thermally grown or deposited on the first bulk silicon substrate, an electrically conductive back gate layer formed on the first oxide layer, and a second oxide layer thermally grown or deposited on the back gate layer; forming a second substrate portion having a second bulk silicon substrate, a silicon germanium (SiGe) layer epitaxially grown on the second bulk silicon substrate, a silicon layer epitaxially grown on the SiGe layer and a third oxide layer thermally grown or deposited on the silicon layer; implanting a hydrogen species through the third oxide layer and the silicon layer, stopping within or beyond the SiGe layer; bonding the first substrate portion to the second substrate portion so as to define a bonding interface between the second and third oxide layers; performing a first annealing procedure to enhance oxide-to-oxide bonding between the second and third oxide layers; performing a second annealing procedure at a higher temperature than the first annealing procedure so as to create a front of connecting voids corresponding to a location of the hydrogen species; separating the bonded structure along the void front; and removing any remaining part of the second bulk silicon substrate and the SiGe layer on the silicon layer so as to define the DBBG SOI wafer structure, wherein the first oxide layer comprises a lower BOX, the bonded second and third oxide layers together comprise an upper BOX, the silicon layer comprises a silicon-on-insulator (SOI) layer, the first bulk substrate comprises a bulk substrate of the DBBG SOI wafer structure, and the back gate layer is disposed between the upper BOX and the lower BOX.

In still another embodiment, a semiconductor wafer structure for integrated circuit devices includes a bulk substrate; a lower insulating layer formed on the bulk substrate; an electrically conductive layer formed on the lower insulating layer; an upper insulating layer formed on the electrically conductive layer, the upper insulating layer formed from a pair of separate insulation layers having a bonding interface therebetween; and a semiconductor layer formed on the upper insulating layer.

In still another embodiment, a double buried oxide (BOX), back gate (DBBG) silicon-on-insulator (SOI) wafer structure for integrated circuit devices includes a bulk silicon substrate; a lower buried oxide (BOX) layer formed on the bulk silicon substrate; an electrically conductive back gate layer formed on the lower BOX layer; an upper BOX layer formed on the back gate layer, the upper BOX layer formed from a pair of separate oxide layers having a bonding interface therebetween; and an SOI layer formed on the upper BOX layer.

### BRIEF DESCRIPTION OF THE DRAWINGS

Referring to the exemplary drawings wherein like elements are numbered alike in the several Figures:

FIGS. 1-7 are various cross-sectional views illustrating a method of forming a double buried oxide (BOX), back gate (DBBG) silicon-on-insulator (SOI) wafer structure, in accordance with an embodiment of the invention, where in particular:

FIG. 1 illustrates the formation of a first substrate portion used for the DBBG SOI structure;

FIG. 2 illustrates the formation of a second substrate portion used for the DBBG SOI structure;

FIG. 3 illustrates the bonding of the second substrate portion to the first substrate portion;

FIG. 4 illustrates an annealing procedure to form a fracture front in the SiGe layer of the bonded structure;

FIG. 5 illustrates the removal of a top portion of the bonded structure following separation at the SiGe layer;

FIG. 6 illustrates the remaining bottom portion of the bonded structure and remaining SiGe layer following wafer separation; and

FIG. 7 illustrates the completed DBBG SOI wafer structure following removal of the remaining SiGe layer and final bonding annealing procedure.

### DETAILED DESCRIPTION

Disclosed herein is a method of fabricating low cost DBBG SOI wafers by eliminating the use of more expensive, preformed SOI wafers as a starting substrate. In brief, the embodiments utilize separate, partially processed bulk silicon wafers that are bonded at one location and then subsequently separated at another location to form a double BOX structure, and with the least need for highly uniform chemical mechanical polishing (CMP) in the substrate fabrication.

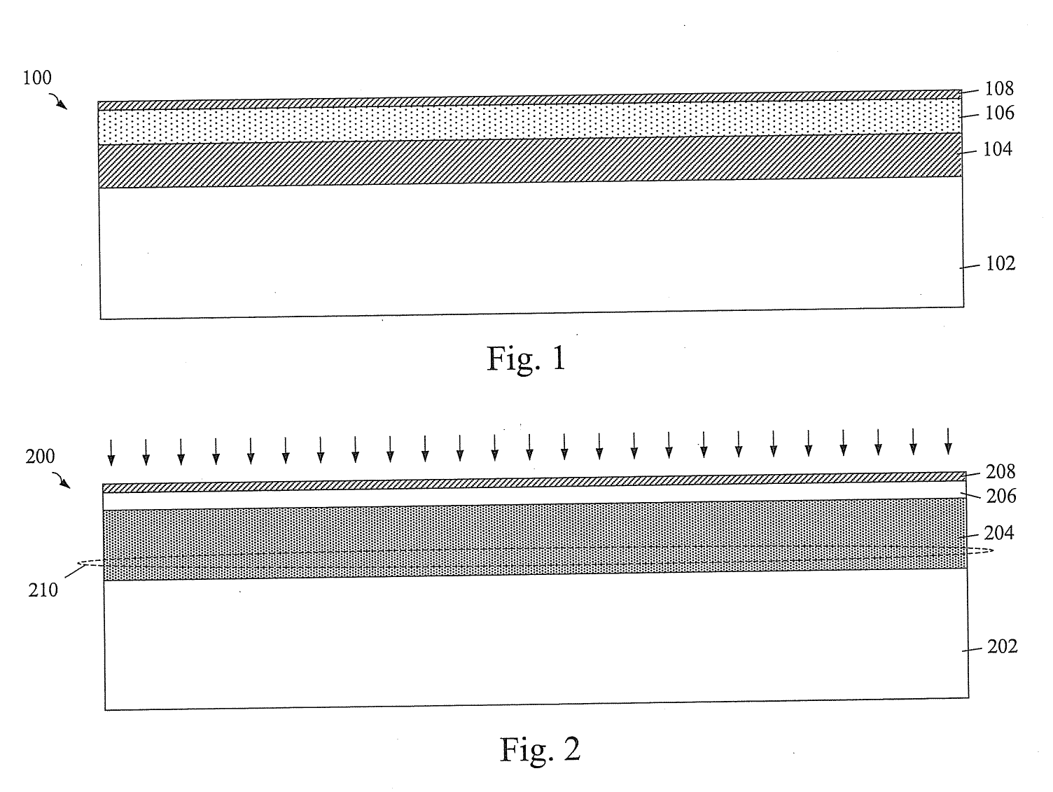

FIG. 1 illustrates the formation of a first substrate portion 100, in which a first bulk silicon substrate 102 has an oxide layer 104 (e.g., 100-200 nanometers (nm) in thickness) thermally grown or deposited thereon. Then, an electrically conductive layer 106 of back gate material (e.g., amorphous silicon, doped or undoped polysilicon, metal, metal silicide, metal nitride, etc.) of about 20-100 nm in thickness is deposited on the oxide layer 104. As further shown in FIG. 1, a relatively thin (e.g., about 5-20 nm) oxide layer 108 is then thermally grown or deposited on top of the back gate layer 106. The oxide layer 108 may be thermally grown or deposited at a temperature of about 600-800° C., for example.

Referring next to FIG. 2, there is shown the formation of a second substrate portion 200, in which a second bulk silicon substrate 202 has a sacrificial silicon germanium (SiGe) layer 204 (e.g., 5-1000 nm in thickness) deposited thereon, at an exemplary Ge concentration of about 10-35%. The SiGe is followed by a thin layer 206 (e.g., about 5-50 nm) of epitaxially grown silicon that will ultimately serve as the SOI layer of the double BOX structure. The silicon layer 206 may be formed in the same processing step as the SiGe layer (e.g., by shutting off a Ge gas source after completion of the SiGe layer formation). As further shown in FIG. 2, a relatively thin (e.g., about 5-20 nm) oxide layer 208 is then thermally grown or deposited on top of the silicon layer 206. With respect to the deposition of the oxide layer 108 in FIG. 1, the oxide layer 208 in FIG. 2 may also be thermally grown or deposited at a temperature of about 600-800° C.

A hydrogen implant step is then performed (indicated by the arrows in FIG. 2) in order to insert a layer of hydrogen species within or beyond the SiGe layer 204, in accordance with the well known Smart-Cut® process described in U.S. Pat. No. 5,374,564. In order to prevent damage to the silicon (SOI) layer 206, the hydrogen species implant conditions should be such that the species stops or peaks at a suitable location in or beyond the SiGe layer 204, such as indicated by implant region 210 in FIG. 2.

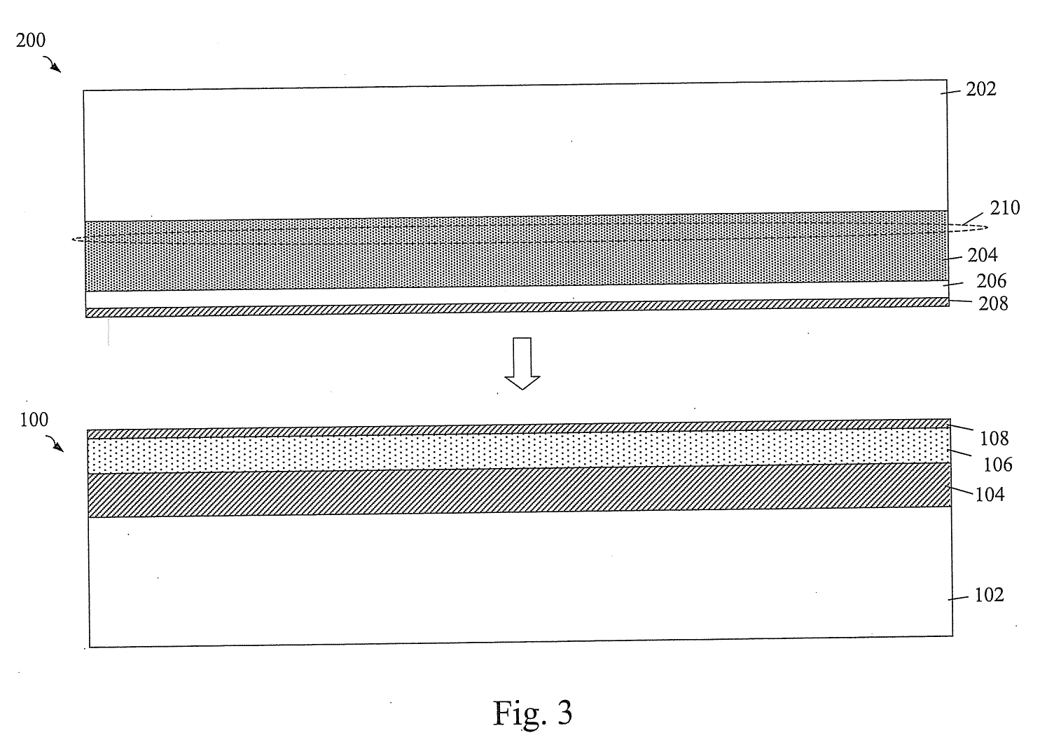

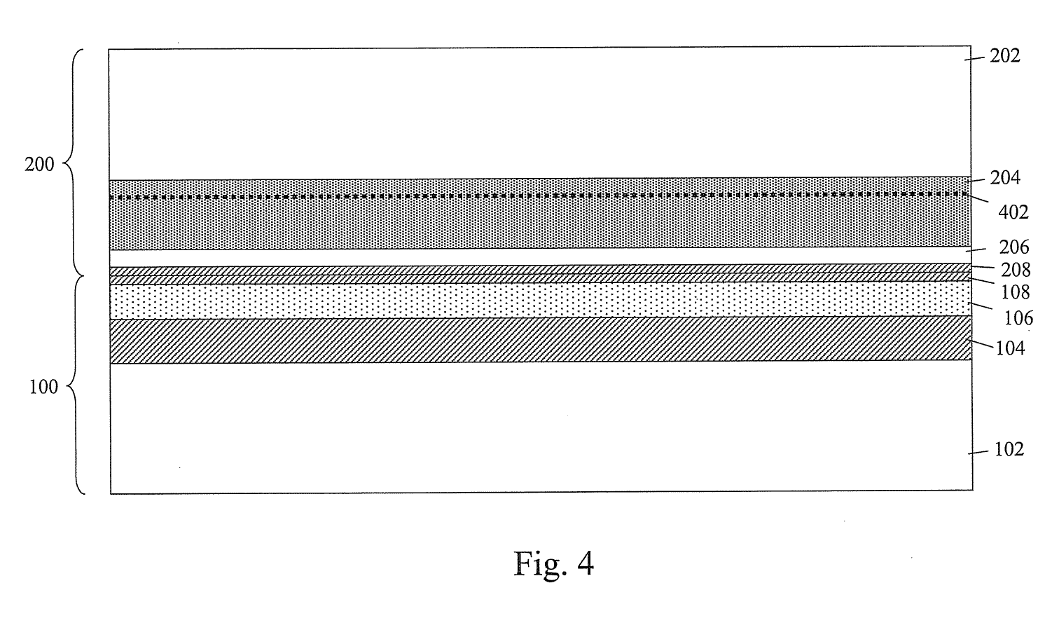

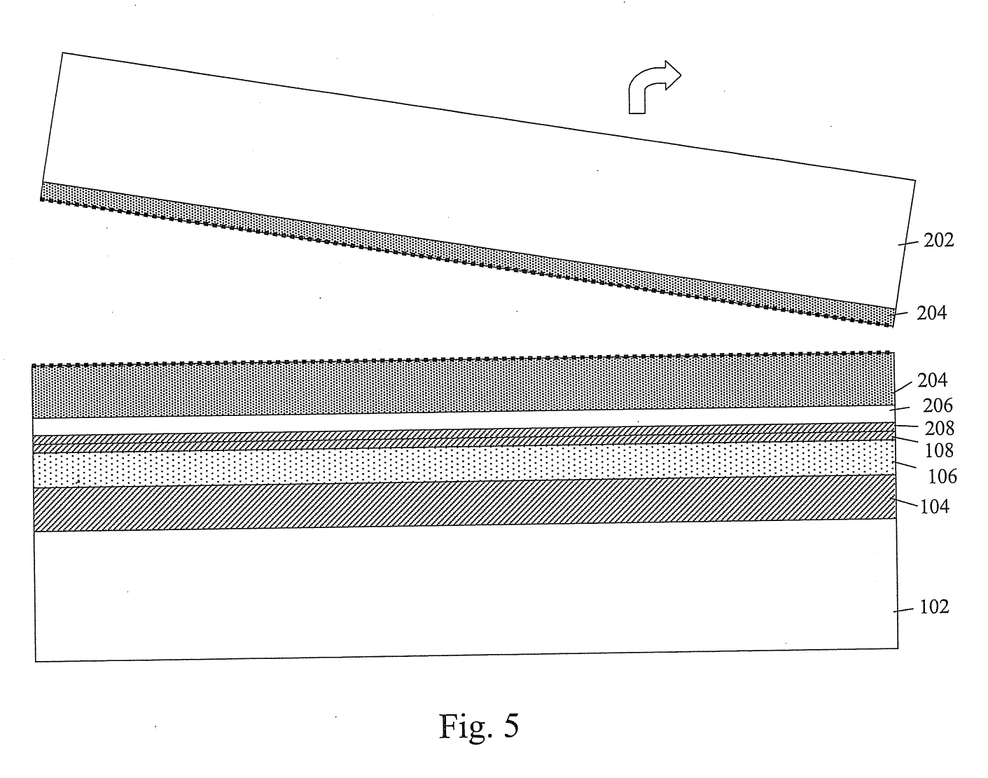

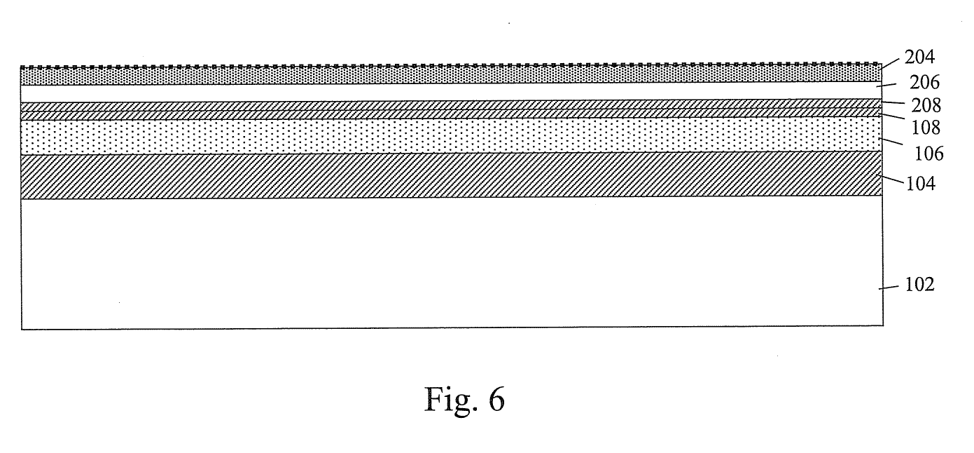

FIG. 3 illustrates the bonding of the second substrate portion 200 to the first substrate portion 100, wherein the thin oxide layer 108 of the first substrate portion 100 is bonded to the thin oxide layer 208 of the second substrate portion 200 through oxide-to-oxide bonding. Thus bonded, layers 108 and 208 combine to define an upper BOX layer for a double BOX substrate. A first annealing procedure (e.g., at about 300° C.) is performed in order to enhance the bonding interface between layers 108 and 208. As then shown in FIG. 4, the structure undergoes a second annealing procedure (at a higher temperature than the first annealing procedure, e.g., at about 400° C.) so as to cause the hydrogen species to form a front of connecting voids 402 of hydride regions within the SiGe layer 204. The structure is then fractured along the front as shown in FIG. 5. The top portion including bulk substrate 202 and a portion of SiGe layer 204 is then removed, leaving the structure as shown in FIG. 6 in which a portion of the SiGe layer 204 remains following wafer separation. Again, it will be appreciated that in the event the implant region 210 is substantially defined beyond the SiGe layer 204 and into the bulk silicon substrate 202 during the implant procedure of FIG. 2, then the separation along the front in FIG. 5 would be depicted within bulk silicon substrate 202, and a portion thereof would remain atop the structure shown in FIG. 6.

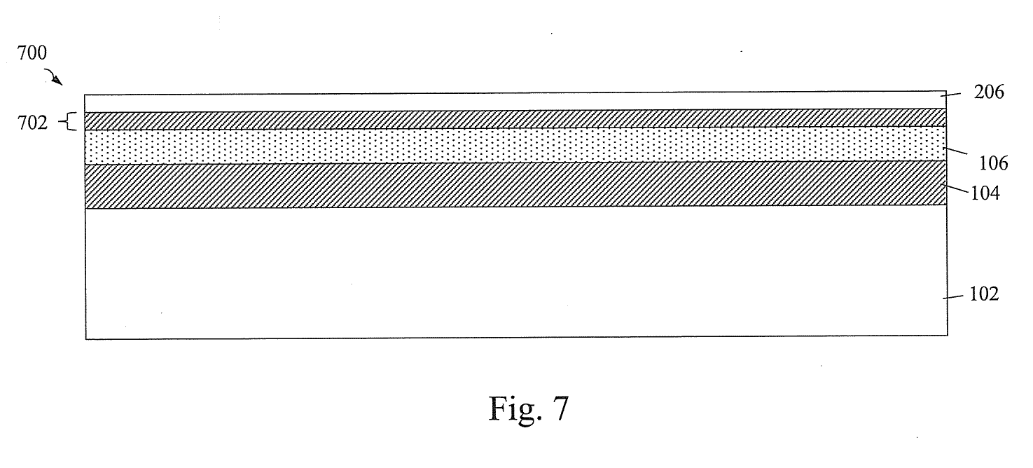

Next, any remaining portion of the second silicon substrate 202 is removed, for example, by polishing or by a selective wet etch with respect to silicon (e.g., a tetramethylammonium hydroxide (TMAH) etch), and the remaining SiGe layer 204 is removed using an etch selective with respect to SiGe such as a hot Huang A type solution (NH₄OH:H₂O₂:H₂O). Finally, another annealing procedure (at a higher temperature than the second annealing procedure, e.g., at about 800-1000° C.) is then performed to further enhance the oxide-to-oxide bonding. As shown in FIG. 7, this results in a double BOX back gate structure 700 having a bulk substrate 102, a lower BOX layer 104 over the substrate 102, a conductive back gate layer 106 over the lower BOX layer 104, an upper BOX layer 702 (having the oxide bonding interface therein) over the back gate layer 106 and an SOI layer 206 over the upper BOX layer 702. Moreover, the DBBG structure 700 is formed in a manner such that an expensive SOI starting substrate is not used beforehand, and in a manner where the thickness of the remaining SOI layer 206 and upper BOX layer 702 are all well controlled.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming a semiconductor wafer structure for integrated circuit devices, the method comprising:
forming a first substrate portion having a first bulk substrate, a first insulating layer formed on the first bulk substrate, an electrically conductive layer formed on the first insulating layer, and a second insulating layer formed on the electrically conductive layer;
forming a second substrate portion having a second bulk substrate, a sacrificial layer formed on the second bulk substrate, a semiconductor layer formed on the sacrificial layer and a third insulating layer formed on the semiconductor layer;
bonding the first substrate portion to the second substrate portion so as to define a bonding interface between the second and third insulating layers;
separating the resulting bonded structure at a location within the second bulk substrate or the sacrificial layer and removing the second bulk substrate; and
removing any remaining portion of the sacrificial layer so as to define a double buried insulator back gate semiconductor-on-insulator structure, wherein the first insulating layer comprises a lower insulating layer, the bonded second and third insulating layers together comprise an upper insulating layer, the semiconductor layer comprises a semiconductor-on-insulator layer, the electrically conductive layer comprises a back gate layer, and the first bulk substrate comprises a bulk substrate of the double buried insulator back gate semiconductor-on-insulator structure.

2. The method of claim 1, wherein the sacrificial layer comprises silicon germanium (SiGe), the first, second and third insulating layers comprise silicon based oxide layers, and the semiconductor layer and the first and second bulk substrates comprise silicon (Si).

3. The method of claim 1, wherein the electrically conductive layer comprises one or more of amorphous silicon, undoped polysilicon, doped polysilicon, metal, metal silicide, and metal nitride.

4. The method of claim 1, further comprising performing an annealing procedure to enhance bonding between the second and third insulating layers.

5. A method of forming a double buried insulator back gate semiconductor-on-insulator wafer structure for integrated circuit devices, the method comprising:
forming a first substrate portion having a first bulk substrate, a first insulating layer formed on the first bulk substrate, an electrically conductive layer formed on the first insulating layer, and a second insulating layer formed on the electrically conductive layer;
forming a second substrate portion having a second bulk substrate, a sacrificial layer formed on the second bulk substrate, a semiconductor layer formed on the sacrificial layer and a third insulating layer formed on the semiconductor layer;
implanting a hydrogen species through the third insulating layer and the semiconductor layer, stopping within or beyond the sacrificial layer;
bonding the first substrate portion to the second substrate portion so as to define a bonding interface between the second and third insulating layers;
performing an annealing procedure so as to create a front of connecting voids corresponding to a location of the hydrogen species;
separating the bonded structure along the void front; and
removing any remaining part of the second bulk substrate and the sacrificial layer on the semiconductor layer so as to define a double buried insulator back gate semiconductor-on-insulator wafer structure, wherein the first insulating layer comprises a lower insulating layer, the bonded second and third insulating layers together comprise an upper insulating layer, the semiconductor layer comprises a semiconductor-on-insulator layer, the electrically conductive layer comprises a back gate layer, and the first bulk substrate comprises a bulk substrate of the double buried insulator back gate semiconductor-on-insulator wafer structure.

6. The method of claim 5, wherein the sacrificial layer comprises silicon germanium (SiGe), the first, second and third insulating layers comprise silicon based oxide layers, and the semiconductor layer and the first and second bulk substrates comprise silicon (Si).

7. The method of claim 5, wherein the electrically conductive layer comprises one or more of amorphous silicon, undoped polysilicon, doped polysilicon, metal, metal silicide, and metal nitride.

8. The method of claim 5, further comprising performing another annealing procedure to enhance bonding between the second and third insulating layers.

9. A method of forming a double buried oxide (BOX), back gate (DBBG) silicon-on-insulator (SOI) wafer structure for integrated circuit devices, the method comprising:
forming a first substrate portion having a first bulk silicon substrate, a first oxide layer thermally grown or deposited on the first bulk silicon substrate, an electrically conductive back gate layer formed on the first oxide layer, and a second oxide layer thermally grown or deposited on the back gate layer;
forming a second substrate portion having a second bulk silicon substrate, a silicon germanium (SiGe) layer epitaxially grown on the second bulk silicon substrate, a silicon layer epitaxially grown on the SiGe layer and a third oxide layer thermally grown or deposited on the silicon layer;
implanting a hydrogen species through the third oxide layer and the silicon layer, stopping within or beyond the SiGe layer;
bonding the first substrate portion to the second substrate portion so as to define a bonding interface between the second and third oxide layers;
performing a first annealing procedure to enhance oxide-to-oxide bonding between the second and third oxide layers;
performing a second annealing procedure at a higher temperature than the first annealing procedure so as to create a front of connecting voids corresponding to a location of the hydrogen species;
separating the bonded structure along the void front; and
removing any remaining part of the second bulk silicon substrate and the SiGe layer on the silicon layer so as to define the DBBG SOI wafer structure, wherein the first oxide layer comprises a lower BOX, the bonded second and third oxide layers together comprise an upper BOX, the silicon layer comprises a silicon-on-insulator (SOI) layer, the first bulk substrate comprises a bulk substrate of the DBBG SOI wafer structure, and the back gate layer is disposed between the upper BOX and the lower BOX.

10. The method of claim 9, further comprising performing a third annealing procedure at a higher temperature than the second annealing procedure to further enhance the oxide-to-oxide bonding between the second and third oxide layers.

11. The method of claim 9, wherein removing the remaining portion of the SiGe layer on the silicon layer comprises applying a hot Huang A type cleaning solution (NH₄OH:H₂O₂:H₂O).

12. The method of claim 9, further comprising removing any remaining portion of the second silicon substrate by applying a tetramethylammonium hydroxide (TMAH) etch that is selective with respect to silicon, and wherein removing the remaining portion of the SiGe layer on the silicon layer comprises applying a hot Huang A type cleaning solution (NH₄OH:H₂O₂:H₂O).

13. The method of claim 9, wherein the SiGe layer has a germanium concentration of about 10 to 35%.

14. The method of claim 9, wherein the electrically conductive back gate layer comprises one or more of: amorphous silicon, undoped polysilicon, doped polysilicon, metal, metal silicide, and metal nitride.

15. The method of claim 9, wherein:
the first oxide layer is about 100 to about 200 nanometers (nm) in thickness;
the back gate layer is about 20 to about 100 nm in thickness;
the second oxide layer is about 5 to about 20 nm in thickness;
the SiGe layer is about 5 to about 1000 nm in thickness; and
the third oxide layer is about 5 to about 20 nm in thickness.

16. A semiconductor wafer structure for integrated circuit devices, comprising:
a bulk substrate;
a lower insulating layer formed on the bulk substrate;
an electrically conductive layer formed on the lower insulating layer;
an upper insulating layer formed on the electrically conductive layer, the upper insulating layer formed from a pair of separate insulation layers having a bonding interface therebetween; and
a semiconductor layer formed on the upper insulating layer.

17. The structure of claim 16, wherein:
the lower insulating layer is about 100 to about 200 nanometers (nm) in thickness;
the electrically conductive layer is about 20 to about 100 nm in thickness;
the pair of separate insulation layers are each about 5 to about 20 nm in thickness, corresponding to a total thickness of about 10 to about 40 nm for the upper insulating layer; and
the semiconductor layer is about 5 to about 50 nm in thickness.

18. A double buried oxide (BOX), back gate (DBBG) silicon-on-insulator (SOI) wafer structure for integrated circuit devices, comprising:
a bulk silicon substrate;
a lower buried oxide (BOX) layer formed on the bulk silicon substrate;
an electrically conductive back gate layer formed on the lower BOX layer;
an upper BOX layer formed on the back gate layer, the upper BOX layer formed from a pair of separate oxide layers having a bonding interface therebetween; and
an SOI layer formed on the upper BOX layer.

19. The structure of claim 18, wherein:
the lower BOX layer is about 100 to about 200 nanometers (nm) in thickness;
the back gate layer is about 20 to about 100 nm in thickness;
the pair of separate oxide layers are each about 5 to about 20 nm in thickness, corresponding to a total thickness of about 10 to about 40 nm for the upper BOX layer; and
the SOI layer is about 5 to about 50 nm in thickness.
